(19) United States
(12) Patent Application Publication
(10) Pub. No.: US 2025/0391758 A1
(43) Pub. Date: Dec. 25, 2025

(54) HALF-BRIDGE MODULE WITH INSULATED CONTACT AREAS BETWEEN TWO TRANSISTOR STRIP SECTIONS

(71) Applicant: SCHAEFFLER TECHNOLOGIES AG & CO. KG, Herzogenaurach (DE)

(72) Inventor: Alexander Kuschel, Regensburg (DE)

(73) Assignee: Vitesco Technologies GmbH, Regensburg (DE)

(21) Appl. No.: 18/868,053

(22) PCT Filed: May 23, 2023
(86) PCT No.: PCT/EP2023/063828

§ 371 Date: Sep. 3, 2025

(30) Foreign Application Priority Data
May 31, 2022 (DE) 10 2022 205 513.6

(51) Int. Cl. H01L 23/498; H01L 25/07; H03H 7/06; H10D 80/20

(52) U.S. Cl. CPC H01L 23/49838; H01L 25/072; H03H 7/06; H10D 80/20

(57) ABSTRACT

A half-bridge module has a carrier including a conductor track layer. The conductor track layer has a first transistor strip section, a second transistor strip section and an intermediate section, each extending along a first direction. The intermediate section is arranged between the first transistor strip section and the second transistor strip section. Connecting surface sections of a first surface, which also extends in the first transistor strip section, extend in the intermediate section. Connection surfaces insulated therefrom alternate with the connecting surface sections in the first direction.

### CROSS-REFERENCE TO RELATED APPLICATIONS

This application claims priority to PCT Application PCT/EP2023/063828, filed May 23, 2023, which claims priority to German Patent Application No. DE 10 2022 205 513.6, filed May 31, 2022. The disclosures of the above applications are incorporated herein by reference.

### BACKGROUND OF THE INVENTION

Vehicles with electric drive include electric machines whose windings are energized in a switchable manner. In order to be able to achieve the required powers of often more than 100 KW, high currents of often more than 100 amperes and operating voltages of often more than 100 V, in particular 800 V, are used. Power transistors that produce switching edges with a high current stroke in a short time are thus used for the switched energization of the windings. In particular, extremely fast-switching transistors, such as SiC transistors, are used to achieve even shorter switching edges or higher current rise rates of the transistors. In order to be able to effectively use such fast-switching transistors in particular, a very low-induction interconnection is required, where signal propagation times must also be taken into account for reliable switching.

### SUMMARY OF THE INVENTION

It is an object of the invention to present high-power transistors to be interconnected to form half-bridges in a low-inductance manner.

This object is achieved by the half-bridge module described. Further properties, features, and embodiments will become apparent from the description and the figures.

It is proposed to divide a conductor track layer of a carrier into two strip sections and an intermediate section that lies between the strip sections. The sections are strip-like and extend in the same direction. The strips thus lie on top of one another (as seen perpendicular to the longitudinal direction of the strips), with the intermediate section being located between the strip sections mentioned first. The two strip sections on both sides of the intermediate section are provided for transistors, which may be applied there for example as bare dies (unpackaged semiconductor components). A low overall inductance is achieved by the presence in the intermediate section of isolated connection surfaces which, due to their proximity, allow direct and short connections into the first upper strip section, and in which, on the other hand, power contact-connection fields may be provided, which are in direct proximity to the lower (second) strip section, such that a contact-connection point on the isolated connection surfaces may be directly adjacent to a contact-connection point of the second strip section. This provides a contact-connection option for the isolated connection surfaces and the lower, second strip section that ensure a very small surface between the connections of the connection surfaces and the second strip section since these are directly adjacent. On the other hand, it is ensured that the current connection from the connection surfaces to the upper first strip section are just as short since the isolated connection surfaces also abut or adjoin the first (upper) strip section. The fact that the connection surfaces are adjacent to both strip sections therefore results in a low-inductance interconnection. The first and second strip sections are provided on both sides of the connection surfaces.

A first surface extends in the (upper) first strip section and further includes connecting surface sections extending into the intermediate section up to the (lower) second strip section. This enables a direct low-inductance connection of the potential of the first surface to contact points in the (lower) second strip section. Due to the connecting surface sections, the first surface adjoins the (lower) second strip section, such that very short connections are possible. The terms below and above refer to a top view of the module, as illustrated for example in FIG. 1, in which the longitudinal direction of the carrier or the conductor track layer leads from left to right. The term strip section is also “strip” for short. The strips align with one another in a direction perpendicular to the first direction (that is to say perpendicular to the longitudinal direction).

In the intermediate section, therefore, the connecting surface sections (as part of the first surface that extends in the first strip) and the isolated connection surfaces alternate along the profile of the strips (that is to say along a first direction or the longitudinal direction). The first surface, which extends over the first strip section and the intermediate sections, and the isolated connection surfaces adjoin the (lower) second strip section, but are electrically isolated therefrom via a trench in the conductor track layer. This means a very short connection option to the second (lower) strip section for the connecting surface sections (that is to say parts of the first surface) and this means a contact-connection option for the isolated connection surfaces, these options being very close to the contact-connection options for the second (lower) strip section. As a result, feed lines to these contact points may be very close to one another. The narrow guiding of the feed lines results in low inductances.

Finally, the connecting surface sections of the first surface, which also extends in the (upper) first strip section, enable contact-connection points for a feed line located substantially in the center between the first and the second strip section. This enables the contact-connection points for feed lines to be arranged at approximately the same distance from components such as transistors that are located in or on the strip sections. Approximately the same signal propagation times to the transistors of the different strip sections are obtained. As a result, a switching edge produced by components on or in the first strip section reaches the contact-connection sections on the connecting surface sections approximately at the same time as switching edges formed in or on the second strip section. This avoids asymmetries upon actuation, and so no signal propagation times need to be adjusted in a controller. Instead, the layout of the conductor track layer alone results in time-symmetry for components of both strips. The terms used here refer to the illustration of FIG. 1, which is discussed in more detail in the description of the figures. The strip sections described here may be populated with transistors, and are therefore also referred to as transistor strip sections.

The conductor track layer described here has a layout including a first surface, a second surface and isolated connection surfaces. These three elements are isolated from one another in the conductor track layer and are electrically isolated by structures of the conductor track layer. The surfaces of the conductor track layer are thus separated; structures of the conductor track layer provide for the electrical isolation of the surfaces. The isolation of the surfaces are provided by etching or milling or other structuring shaping measures.

The conductor track layer is further geometrically divided into two strip sections and an intermediate section in between. This division into sections is merely conceptual or functional, whereas the surfaces are physically and electrically isolated from one another in the conductor track layer. A division into strips does not necessarily mean an electrical subdivision, but does not exclude this. The strip sections and the intermediate section are directly lined up together (in a direction perpendicular to the first direction). The sections completely cover the carrier or a power region thereof. In an embodiment, the sections are aligned in a direction perpendicular to the first direction. As with the surfaces, the sections refer to the largest side surface of the carrier (that is to say in top view, not a cross section). The conductor track layer is a conductive outer layer of the carrier. The strip sections each extend from an outer edge of the conductor track layer to the intermediate section. These outer edges extend along the first direction along the longest edge of the carrier. The strip sections and the intermediate section extend from one side to the opposite side of the conductor track layer, with these sides being perpendicular to the outer edges. In the case of a rectangular carrier, these sides are the shorter sides of the rectangle and the outer edges are the longer sides of the rectangle.

The first surface extends over a first strip section as well as over connecting surface sections, which protrude from the first strip section into the intermediate section and adjoin the second strip section. The section of the first surface, which is located in the first strip section, and the connecting surface sections are electrically connected to one another by being formed in one part or else by electrical connection elements. The first surface is electrically isolated from the second surface (by structures of the conductor track layer), since the conductor track layer has a gap between the surfaces, with the gap extending through the entire thickness of the conductor track layer. This gap, or the resulting trench, extends between the second surface and the connecting surface sections.

The isolated connection surfaces are surrounded on the one hand by the connecting surface sections of the first surface (within the intermediate section) and by (a part of) the first surface that extends in the first strip section, and are further surrounded by (sections of the) second surface. The second surface may have an edge that extends substantially along the first direction (along which the strip sections or intermediate sections also extend). The first surface and the connection surfaces come up to this edge (with the exception of an electrically isolating trench). An edge parallel to this may correspond to an outer edge.

The connecting surface sections and isolated connection surfaces come up to the second surface. However, the connecting surface sections and the isolated connection surfaces are electrically isolated from the second surface by structures in the conductor track layer. Between the first surface, the second surface and the connection surfaces, the conductor track layer has isolating structures that extend through the entire thickness of the conductor track layer. The structures are recesses, such as gaps or trenches. The resulting distance between these surfaces may correspond to a minimum creepage distance to ensure that the surfaces are sufficiently isolated from one another.

The first surface, the second surface and the connection surfaces extend in the same conductor track layer. The conductor track layer is thus merely structured by the trench that separates the second surface from the first surface and the connection surfaces, and the trench that separates the insulated connection surfaces from the first surface. In an embodiment, the connection surfaces and the connecting surface sections may repeat several times in succession along the first direction so as to enable a symmetrical connection with regard to propagation times. This ensures that components on the first surface and components on the second surface are contact-connected in the same way in electrical terms (that is to say with regard to the inductance per unit length of the connection and with regard to propagation time and the resistance of the connection).

One side of the conductor track layer forms an outer side of the carrier. In other words, the conductor track layer is not an intermediate layer of a multilayered carrier, but forms the top side or underside of the carrier. The carrier further includes an insulator layer to which the conductor track layer is applied. The conductor track layer is a metal layer, such as a layer of copper or a copper material or of aluminum or an aluminum material. The insulator may be a plastic, a plastic composite or a ceramic insulator. The carrier may be designed for example as a printed circuit board, as a DCB printed circuit board or as an IMS printed circuit board. The carrier may be in single-layer form, wherein the layer is formed by the conductor track layer, or may be in multilayer form, wherein one of the two layers is formed by the conductor track layer. Further conductive layers may also be provided within the carrier, wherein the conductor track layer is the outer layer of the carrier. The outer layer may be provided with an insulating coating. The coating is removed at the contact points for supply lines or in regions where a component is to be attached.

The conductor track layer is of structured form, that is to say it forms conductor track structures. These conductor track structures include the first surface, the second surface and/or the isolated connection surfaces as described herein. In an embodiment, the conductor track layer extends in one plane. In a single-layer configuration of the carrier, the carrier may be connected to a heat sink on the side facing away from the conductor track layer. An insulation layer of the carrier may be connected to the heat sink, or a conductive layer of the carrier may be connected to the heat sink, which is provided on the opposite side of the conductor track layer. The half-bridge module may be populated or unpopulated.

The carrier is used within a half-bridge module. A (populated) half-bridge module includes a plurality of parallel-connected high-side transistors and a plurality of parallel-connected low-side transistors. The high-side transistors are connected in series with the low-side transistors via a connecting point. The connecting point may serve as a phase connection or load connection, while the two ends of this series connection may be connected to a supply voltage, that is to say to two supply potentials. The high-side transistors may be placed in the second strip section (or on the second surface) using the present configuration, while the low-side transistors may be arranged on the first strip section (or on the first surface in the first strip section). Since the two strip sections mentioned above are suitable for placing transistors, the strips are also referred to as transistor strips.

The carrier may have a rectangular shape, with the long side corresponding to the first direction along which the strip sections also extend. The first strip section, the intermediate section and the second strip section are lined up transversely thereto. The carrier may further include a power section on which the strip section and the intermediate section are located, and may further include at least one further section, for example for connection technology, filter, control system and the like. However, the carrier terminates with edges of the two strip sections. The strip sections are arranged in opposite directions to one another, whereby edges perpendicular thereto terminate the strip sections and the intermediate section in the longitudinal direction. The first direction extends along the longer edge of the rectangular shape of the carrier, but may also extend along the shorter edge of the rectangular shape of the carrier.

The invention thus proposes a half-bridge module including a carrier having a conductor track layer. The carrier is applied to an insulator layer and has an uncovered surface (top side) opposite the side of the conductor track layer (underside) adjacent to the insulator layer. The conductor track layer has three sections in the form of strips. These strips each extend along a first direction. The strips extend parallel to one another in this direction. The conductor track layer has a first transistor strip section, a second transistor strip section and an intermediate section (which may also be referred to as an intermediate strip section because it has a strip shape like the other two strip sections). The shape of the strip sections is the shape of a rectangle, wherein the length of each rectangle corresponds to the length of the conductor track layer and the sum of the widths of the strip sections and the intermediate section together result in the width of the conductor track layer.

The conductor track layer is structured and is designed in accordance with a layout as mentioned above. The intermediate section is located between the first and the second transistor strip section. There is thus a sequence transverse to the first direction, that is to say along the width of the conductor track layer: first transistor strip section, intermediate section and second transistor strip section. These sections relate to a plane in which the conductor track layer extends. The strips therefore extend in the same surface or in the same plane. The strip sections and the intermediate section fill most or all of the conductor track layer. The strip sections and the intermediate section are functional subdivisions of the conductor track layer and are not necessarily also electrical subdivisions. There is a first surface that extends both in the first strip section and in the intermediate section, wherein there is no electrical subdivision between the surface subregions that extend in the intermediate section and surface subregions that extend in the first strip section.

Connecting surface sections of a first surface extend in the intermediate section. This first surface also extends in the first transistor strip section. The connecting surface sections are electrically connected to the surface that extends in the first strip section. The first strip section is substantially fully or at least mostly filled by the first surface, wherein, in the intermediate section, only subregions of the intermediate section are covered by the first surface (and form the connecting surface sections).

There are also isolated connection surfaces in the intermediate section. These are filled in the same way as the subregions of the intermediate section. However, these subregions do not overlap with the connecting surface sections. The connecting surface sections are electrically isolated from the connection surfaces. The electrical isolation between connection surfaces and connecting surface sections relates to the conductor track layer, which may have separating structures in the conductor track layer for the purpose of electrical isolation. In other words, the connection surfaces are isolated from the connecting surface sections in that the surface of the conductor track layer representing the connection surfaces is separated from the connecting surface sections in the conductor track layer. However, this does not necessarily mean that these two surfaces outside the conductor track layer are electrically connected to one another, for example indirectly via a component or similar.

The connection surfaces are therefore isolated from the connecting surface sections in such a way that the conductor track layer itself does not establish a connection between these two surfaces or surface sections. The isolation of the connection surfaces with respect to the connecting surface sections is produced by physical separation in the conductor track layer, for example by providing a trench between the connection surfaces and the connecting surface sections. In the same way, a second surface (of the same conductor track layer) in the second strip section may be separated from both the connecting surface sections and the connection surfaces.

In the intermediate section, the isolated connection surfaces and the connecting surface sections alternate along the first direction. The first direction runs along the longitudinal direction of the strip sections or the longitudinal direction of the conductor track layer or the carrier or else the intermediate section. This first direction is perpendicular to a second direction. The first and second directions are directions in which the conductor track layer extends over the entire surface area. Both directions are perpendicular to the extent of the conductor track layer thickness.

The first strip section, the intermediate section and the second strip section are lined up along the second direction. In other words, in the second direction, the region of the first surface that lies in the first strip section, the connecting surface sections and connection surfaces alternating in the first direction, and, as a third, the second surface or the second strip section, are lined up together. Since the connecting surface sections and the connection surfaces alternate in the first direction (and within the intermediate section), it is apparent that in a first longitudinal position the first strip section, the connecting surface sections and the second strip section are lined up together, while in a second longitudinal position the first strip section, the connecting surfaces and the second strip section are lined up together. In a first sectional view, perpendicular to the first direction, the first surface (including the connecting surface sections) may adjoin the second surface, while, in a second sectional view, perpendicular to the first direction, the first surface, the connection surfaces and the second surface may be lined up together. The first and second sectional views are in the first direction (that is to say the longitudinal direction) at different positions.

The connecting surface sections adjoin the second transistor strip section. A second surface of the conductor track layer, which extends mostly or substantially fully into the second strip section, is electrically isolated from the connecting surface sections (which are associated with the first surface). The connection surfaces also adjoin the first transistor strip section, but are electrically isolated from the first surface, which extends (inter alia) in the first strip section. The connection surfaces are electrically isolated from the connecting surface sections within the conductor track layer. The surfaces mentioned here are conductive surfaces of the conductive layer formed by the conductor track layer. The sections refer to geometric divisions of the conductor track layer and are not necessarily to be understood as electrically isolated subregions of the conductor track layer. While the first surface extends in the first strip section and (as connecting surface sections) in the intermediate section (and thus a connection exists between surface regions of different strips), the second surface extends in the second strip section, so that the surface in the second strip section is separated from the intermediate section and from the first strip section within the conductor track layer. Surfaces within the first strip section and surfaces in the intermediate section are provided separately to the surface in the second strip section. Separation is provided by separating structures in the conductor track layer.

The connecting surface sections or the first surface and/or the connection surfaces adjoin the second transistor strip section, but are not electrically connected (by the conductor track layer) to the second surface located in the second strip section. The connection surfaces adjoin the second strip section, but without being electrically connected to the second surface located therein (by the conductor track layer). The connection surfaces are provided electrically separate from the first surface by the conductor track layer, such as from the part of the first surface located in the first strip section, and from the connecting surface sections. The conductor track layer thus has a separating effect by being structured in conductor tracks or pads or by having separating structures such as recesses between the surfaces that are to be separated. The conductor track layer has an isolating effect by having trenches or recesses that extend through the entire thickness of the conductor track layer. These trenches, or gaps, or recesses provide for a physical separation between surfaces, surface sections or surface subregions of the conductor track layer. However, the carrier includes at least one insulation layer to which the conductor track layer is attached, so that, despite physical separation in the conductor track layer, there is a mechanical connection (which is electrically isolated, however).

The connecting surface sections widen toward the second transistor strip section. In other words, the portions of the first surface representing the connecting surface sections widen toward the second transistor strip section. The widening is thus effected along the second direction or perpendicular to the first direction, in the plane of the conductor track layer. As an alternative or in combination, the connection surfaces taper toward the second transistor strip section. In this context, tapering refers to a decreasing width. This tapering or decreasing width also refers to the profile along the second direction. The widening or tapering refers to the dimensioning of the respective surfaces or sections in the longitudinal direction, that is to say along the first direction. As an alternative, the width of the connecting surface sections from the first to the second strip section may remain the same or may also decrease. In the same way, the connection surfaces widen from the first to the second strip section, or the width remains the same. The dimensioning in the longitudinal direction (=first direction) is also considered as width here. As an alternative option, provision be may be made for the connection surfaces to have a larger width at the point at which they adjoin the first strip section than at the point or edge at which they adjoin the second surface or the second strip section. Between these points, the profile may also be discontinuous or provide a tapered portion and a widened portion. In addition, the width of the connecting surface sections is smaller at the point at which they adjoin the first strip section than at the edge by which the connecting surface sections adjoin the second strip section or the second surface. The thickness of the conductor track layer is constant (apart from the points where it has recesses).

The connection surfaces may have multiple connecting points in a region adjacent to the first strip section. From each connecting point, at least one connector may extend into the first strip section, to mounting surfaces for components or to the components themselves. Furthermore, the connection surfaces may have connection points, with a connection element configured for contact-connecting a supply potential. In addition, the connecting surface sections may have multiple connecting points in a region of the connecting surface sections adjacent to the second strip section. From each connecting point, at least one connector may extend into the second strip section to mounting surfaces for components or to a component itself. If multiple connectors extend from one connecting point, they may be connected to multiple components in one of the strip sections or lead to multiple mounting surfaces in the respective strip section. In addition, multiple connectors that extend away from the same connecting point may be connected to the same component in one of the strip sections or may lead to the same mounting surface in order to increase the current carrying capacity. Multiple connector groups may extend away from at least one connection surface and/or from at least one connecting surface section, each group having multiple connectors that are provided for connecting the same component or that extend to the same mounting surface.

The first surface and/or the second surface are each continuous surfaces. The subregion of the first surface that extends in the first strip section, together with the connecting surface sections, is a continuous surface (or at least directly electrically connected). This subregion of the first surface that extends in the first strip section is formed as a continuous strip, such as a strip that is continuous along the first direction (and also along the second direction).

The connecting surface sections that are also part of the first surface are not continuous in the first direction, but alternate with the connection surfaces. The connecting surface sections extend to the second transistor strip section from the subregion of the first surface that extends in the first strip section, that is to say from the continuous strip. The connecting surface sections extend to the second surface. The connecting surface sections thus have an edge (which may extend along the first direction) that is opposite the second surface or the second strip section. In the conductor track layer, a trench (or other separating structure) is located between the edge of the connecting surface sections, which point to the second surface or to the second strip section, and the second strip section or the second surface itself. The second surface may have an edge that is opposite the edge of the connecting surface sections. The edges of the connection surfaces provided on the side of the second surface or the second strip section also run substantially along the first direction. The continuous formation of the connecting surface sections and the subregion of the first surface that extends into the first strip section enables an electrical connection, for example of components in the first strip section with contact-connection or connecting elements in the connecting surface sections.

A second surface is provided in the second strip section. This second surface is of conductive design, for example made of a copper material, an aluminum material or another electrically conductive material. The second surface is in the form of a continuous surface in the first direction. The second surface is isolated from the first surface, that is to say from the connecting surface sections, as well as from the connection surfaces (by separating structures in the conductor track layer). A trench that extends through the entire thickness of the conductor track layer is located between the second surface on the one hand and the connecting surface sections of the first surface and the connection surfaces on the other hand. The second surface may have mounting surfaces for transistors. The transistors or the associated mounting surfaces are lined up along the first direction. The transistors may extend along one or more rows along the first direction. These rows extend along the first direction. Mounting surfaces that may be offset from one another perpendicular to the first direction, periodically or alternately, are created. This is the case if the mounting surfaces are arranged in multiple rows (parallel rows) along the first direction. The mounting surfaces are thus lined up together in the second surface along the first direction along one or more rows. The rows extend along the first direction. Embodiments of the half-bridge module with mounting surfaces are unpopulated half-bridge modules in which, however, already the arrangement of the mounting surfaces on the second surface guarantees small distances from the connection surfaces and the connecting surface sections, which results in a low-inductance layout. The mounting surfaces are configured for populating with an SMD component such as a transistor.

The first surface also has mounting surfaces in the first strip section. These are suitable for transistors, like the above-mentioned mounting surfaces, that is to say designed for SMD mounting of a bare-die transistor or for populating with transistors based on another connection technology. The mounting surfaces are lined up together along the first direction. Like the above-mentioned mounting surfaces, they are lined up together along the first direction at a distance and do not fit directly together. The mounting surfaces may be arranged in one or more rows that extend along the first direction. In other words, the mounting surfaces may be provided at different heights, relative to a direction perpendicular to the first direction, that is to say may alternately be at different distances from a center line along the first direction. A half-bridge module with such mounting surfaces is unpopulated. The mounting surfaces are designed for high-current applications, that is to say for continuous currents of at least 10 A or at least 100 A. This also applies to the transistors for populated modules.

The connecting surface sections of the first surface that extend from the first strip section to the second strip section (and thus extend in the intermediate section) result in very low-resistance connections that are produced cost-effectively. Furthermore, the above-mentioned arrangement of the mounting surfaces in the first strip section automatically results in short connecting distances from the connection surfaces (located in the intermediate section), whereby a connection to the first surface or to components or connection elements on the connection surfaces is realized with a low inductance.

A respective group of connection elements is provided on the first surface, on the connecting surfaces and in the second strip section (that is to say on the second surface). The group of connection elements on the first surface is located in the first strip section and thus along the strip of the first surface that extends continuously in the first direction. Each group of connection elements includes multiple connection elements which are lined up together along the first direction (at a distance). A group may also have multiple subgroups of connection elements, each of which are lined up together along a row in the direction of the first direction, but wherein the rows are offset to one another perpendicular to the first direction. The connection elements may be in the form of a sintering pad, contact surface, soldering pad, welding surface, connection pin, connection plate piece or mounting hole. The connection elements have flat sections that extend on the conductor track surface so that a flat connection to the conductor track layer is produced. Connection pins may be provided, these being for example pressed into the conductor track surface, or attached to it (for example by welding, such as friction welding, or soldering or sintering, or the like). The connection elements are electrically conductive. A supply line is used, such as a connection plate piece, wherein the supply line has end sections that are fastened to the conductor track surface over the entire surface thereof. For each first surface, for each second surface, and for the connection surfaces, multiple end sections or contact points are provided for this purpose in order to distribute the connection of the supply lines. The contact points associated with the same potential are lined up together (spaced apart) along the first direction. In one example, the connection elements are designed as mounting holes, for example to be connected by a screw or press fit pin connection or groove connection.

Elements that are electrically connected to one another via the conductor track layer and are arranged along the first direction next to one another or extend in this direction are referred to as a group of connection elements. If the second strip section or the second surface is provided for a positive DC voltage supply potential, and the connection surfaces are provided for a negative DC voltage supply potential, then a low inductance is obtained simply by the proximity of the respective connection elements. In an embodiment, the connection elements of the first surface are associated with a phase potential, wherein then connection surfaces for the phase result on one side on the first surface, and on the other side connection elements on the second strip section and on the connection surfaces associated with the DC voltage supply potentials. In this way, coupling of a clocked signal at the phase potential to the potentials of a supply voltage is prevented or reduced. The connection elements of the phase potential are outside a range that extends from the connection elements of the first supply potential to the connection elements of the second supply potential.

A semiconductor module with connection surfaces is unpopulated. However, as mentioned, the arrangement of the connection surfaces results in a low-inductance connection option as well as a general low-inductance layout.

One embodiment makes provision for the group of connection elements located on the first surface to be provided in the intermediate section. In other words, in these embodiments, the group of connection elements located on the first surface is located on the connecting surface sections. This results in a current path to the mounting surfaces on the first surface for these connection elements that is approximately the same length as the current path to the mounting surfaces (for transistors) on the second surface. This symmetry results in improved signal properties, especially for edges with high rate of rise and also in relation to the resistance of the connection of the mounting surfaces/transistors. One embodiment makes provision for the group of connection elements located on the first surface to be located in the center between a row of mounting surfaces in the first strip section and a row of mounting surfaces in the second strip section. The deviation from this center is not more than 20, 15, 10 or 5 mm.

First connectors start from the connection surfaces. These extend into the first strip section. The connectors are located on the top side of the carrier or above the conductor track layer. The connectors start from a region of the connection surfaces facing the first strip section. The connectors extend into the first strip section and may be connected to contact surfaces there. These contact surfaces may be parts of the first surface, but may also be designed for the application of components. An end of the connector opposite the connection surfaces is designed for physical connection to a contact surface of a component. A first connector starts from a connection surface and extend into the first strip section (or over a half-space above it), or multiple connectors are connected to the same connection surface and extend to different locations of the first strip section. This enables multiple elements in the strip section to be connected to the same connection surface.

Further embodiments make provision for the half-bridge module to have second connectors that are connected to the connecting surface sections. The second connectors extend from these connecting surface sections over the carrier into the second strip section. In this case, the second connectors extend from the connecting surface sections in a half-space above the carrier or the conductor track layer into the second strip section. The second connectors have ends that are opposite to the connecting surface sections and arranged to be connected to elements in the second strip section, for example by contact points of the strip section or by contact surfaces formed for connecting components in the second strip section, for example metallization surfaces of components. Multiple second conductors may extend away from one connecting surface section into the second strip section.

The connectors are designed as bonding wires or bonding strips and may be made of a conductive material such as copper material or aluminum material. The second connectors are connected to the connecting surface sections in a region adjacent to the second strip section. The connectors may be of one-part or multi-part form, having end contact elements and a conductor that connects these end contact elements to one another. The end contact elements may be designed for example as pins, screw elements or connection plate pieces or else bonded conductor ends.

The half-bridge module may be provided as a partly populated, populated or unpopulated module. In an embodiment, the half-bridge module may be populated with surface-mounted components, that is to say with SMD components. The half-bridge module may be populated with first and second transistors as a populated half-bridge module. The first surface of the conductor track layer located in the first strip section may be populated with the first transistors. In other words, the first transistors are provided on the surface section of the first surface located in the first strip section, that is to say in the section in which it is continuous along the first direction. The second surface that extends in the second strip section may be populated with the second transistors. Since these strip sections are provided for populating transistors in the case of unpopulated half-bridge modules and the strip sections are populated with the transistors in the case of populated half-bridge modules, these are also referred to as first and second transistor strip sections. In addition to population using SMD technology, it is also possible to populate using through-hole technology or using embedded technology.

The transistors each have first power path contact surfaces facing the conductor track. The first power path contact surfaces are connected to the first surface. These contact surfaces are the contact surfaces of the transistor and are thus connected to the emitter, collector, source or drain of the transistors. The transistors furthermore have second power path contact surfaces facing away from the first contact surfaces. The second contact surfaces are thus accessible from above in the case of mounted transistors and form a surface above the conductor track layer. However, the first contact surfaces when the transistor is mounted are not accessible from above, as they are facing the conductor track layer and are thus covered by the transistor itself.

The second power path contact surfaces are also contact surfaces that are connected to a collector, an emitter, a drain or a source of the transistors. The first and second contact surfaces are connected to different electrodes of the transistor. The first contact surfaces may thus be connected to the collector, while the second contact surfaces are connected to the emitter, or vice versa. The first contact surfaces may be connected to the source of the transistor, while the second are connected to the drain, or vice versa.

The connection of the second contact surfaces is provided via connectors, such as the connectors described herein. The second contact surfaces of the first transistors provided on the first surface are connected to the connection surfaces (in the intermediate section of the conductor track layer). The second contact surfaces of the second transistors are connected to connecting surface sections. This connection is direct and leads via first and second connectors. The connectors extend over the carrier. The first connectors that connect the connection surfaces to the contact surfaces of the first transistors extend from the connection surfaces into the first strip section to the contact surfaces of the first transistors. The connectors that are connected to the connecting surface sections extend to the contact surfaces of the second transistors connected in the second strip section. The connectors establish a conductive connection between the contact surfaces of the transistors and the connection surfaces or the connecting surface sections. The connectors may directly adjoin the contact surfaces, or there may be a connecting layer between the contact surfaces and the connectors, such as a sintered layer, a solder mediation layer and/or a conductive buffer layer for reducing mechanical stresses. The contact surfaces (=metallization surfaces) described above are power path contact surfaces.

The transistors may also have signal contact surfaces, which are referred to herein as such. The half-bridge module in populated form has a half-bridge formed by a low-side transistor element and a high-side transistor element and an internal connection between the transistor elements. Each transistor element of the half-bridge is formed by multiple transistors connected in parallel. The parallel connection of the transistors results in a multiple of the current carrying capacity for the resulting transistor element. The internal connection includes the first surface or at least subregions thereof. The internal connection leads over the connecting surface sections. The internal connection may further include connectors, such as connectors that extend from the connecting surface sections into the second strip section.

Embodiments make provision for the internal connection between the transistor elements to lead from the first contact surfaces of the first transistors to the first surface, such as sections of the first surface that extend in the first strip section, from where the first surface continues to the connecting surface sections. The internal connection is continued by the connecting surface sections (that is to say from the first surface) by connectors that lead to second contact surfaces of the second transistors. Starting from the first transistors or from their contact surfaces, a portion of the internal connection thus extends along a surface section of the first surface located in the first strip section, where the internal connection is continued form there through the connecting surface sections, also being part of the first surface and located in the intermediate section.

The fact that the connecting surface sections abut the second surface or the second strip section results in only short distances for the connectors carrying the internal connection from the connecting surface sections to the second transistors. The internal connection may further include connecting elements located on the contact surfaces of the transistors, for example solder layers, solder mediation layers, sintered layers and/or conductive buffer layers for reducing the mechanical stress. Although the first transistors and the second transistors are located on strip sections between which the intermediate section is located, the connecting surface sections protruding from the first strip section to the second strip section result in a short and well-conducting connection (as part of the internal connection) provided by the conductor track layer.

The two opposite ends of the half-bridge are realized by the connection surfaces on the one hand and the second surface (in the second strip section) on the other hand. The connecting surfaces and the second surface may each have power contact fields (or other connection elements), for example in order to apply a DC supply voltage to the surfaces. The connection surfaces form a connection for a negative supply potential and the second surface forms a connection for a negative DC supply potential. The power contact-connection fields provided on the connection surfaces may form the negative connection for the half-bridge. The power contact-connection fields provided on the second surface may form the positive connection for the half-bridge. The power contact-connection fields provided on the first surface may form the phase connection for the half-bridge (and be connected to the internal connection thereof).

The first surface may be formed as a connection for the connecting point or for a phase potential or AC potential. The first surface may serve as a load connection.

The transistors may each have at least one signal contact surface. The signal contact surfaces of the first transistors are provided on a side of the transistors facing away from the intermediate section, that is to say facing outwardly to a longitudinal edge (relative to the first direction). The signal contact surfaces of the second transistors are provided on a side of the second transistors facing away from the intermediate section, that is to say facing a second longitudinal edge opposite the first longitudinal edge. This enables the signal contact surfaces to be contact-connected from the outside over short distances. The signal contact surfaces are control signal contact surfaces, such as gate contacts or base contacts. In addition, the signal contact surfaces may serve as monitoring signal connections, for example as temperature signal connections or current measuring connections.

The half-bridge module may also have a filter circuit (in unpopulated, partly populated or fully populated form). The half-bridge module is populated with a filter circuit that short-circuits high-frequency signal components. The filter circuit may be in the form of a snubber filter. The filter circuit may be arranged in the second transistor strip section on the second surface. Furthermore, the filter circuit may be arranged on the connection surfaces. In addition, provision may be made of a filter circuit including both at least one component on the second surface or in the second strip section and at least one component on the connection surfaces (or the connecting surface sections).

The half-bridge module is a half-bridge module of an inverter module, wherein an inverter module includes multiple half-bridge modules. The inverter module may be in the form of a vehicle traction inverter. The half-bridge module is a high-voltage module with a nominal voltage of more than 60 V or of at least 200 V, 400 V, or 800 V. In addition, a vehicle-based charging circuit may be provided with a power factor correction filter having at least one of the half-bridge modules. Finally, a vehicle-based, clocked DC-DC voltage converter may be provided, the operating switches of which proceed from the half-bridge module.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

FIGS. 1, 2a-c and 3 are used for more detailed explanation of exemplary embodiments of the half-bridge module.

### DETAILED DESCRIPTION OF THE PREFERRED EMBODIMENTS

The following description of the preferred embodiment(s) is merely exemplary in nature and is in no way intended to limit the invention, its application, or uses.

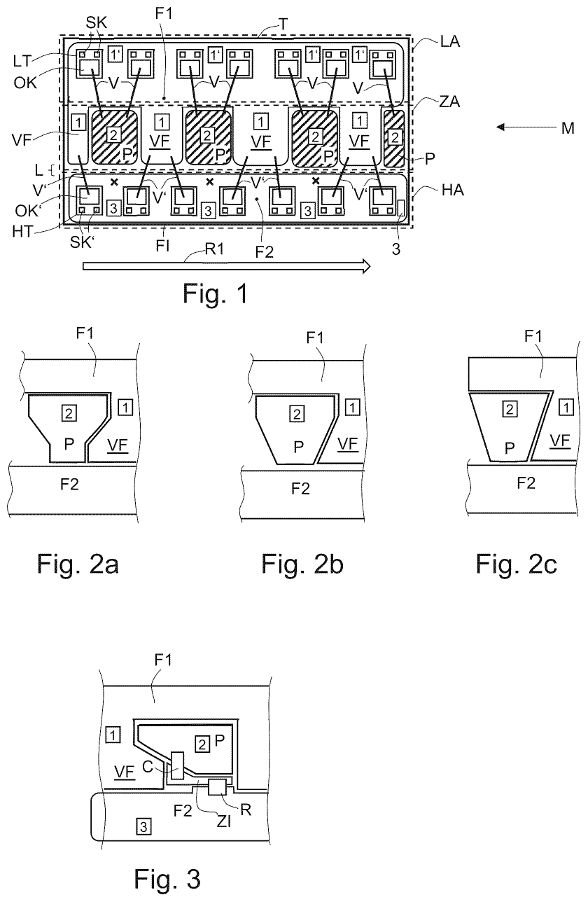

FIG. 1 schematically shows the top view of a half-bridge module M having a carrier T, on which a conductor track layer is located. The conductor track layer is structured into multiple surfaces F1, F2, that is to say divided from an electrical point of view, and is geometrically or functionally divided into multiple sections LA, ZA, HA for more detailed description below.

The sections used for the geometric subdivision of the conductor track layer are a first strip section LA, a second strip section HA and an intermediate section located between the strip sections. In the example shown, the strip sections directly adjoin the intermediate section. Thus, the entire surface or conductor track layer shown is subdivided into the two strip sections and the intermediate section with the reference signs LA, HA and ZA. The intermediate section ZA also has a strip shape. The sections align with one another perpendicular to the first direction R1.

The strip sections LA, HA and the intermediate section ZA are shown in the form of (rectangular) strips that extend along a first direction R1 by way of their longer dimension. A second direction runs perpendicular to the direction R1 in the plane of the drawing, along which second direction the first strip section LA, the intermediate section ZA and the second strip section HA are lined up together (in this order). The direction R1 extends along the length of the rectangular carrier illustrated, while the direction R2 extends along the width (that is to say along the shorter dimension of the rectangle). The entire surface or top side of the carrier is divided into the sections LA, HA and ZA. Provision may also be made of a carrier that, in addition to at least one further region, has a power region subdivided into the sections LA, ZA and HA.

The first surface F1 extends on the one hand in the first strip section LA, wherein the surface F1 substantially fully fills this strip section in FIG. 1. The surface F1 extends further in the intermediate section ZA and forms connecting surface sections VF. While in the first strip section the first surface is continuous (especially in the direction R1), the first surface in the direction R1 within the intermediate section ZA is repeatedly interrupted (by isolated connection surfaces P). Thus, there are multiple connecting surface sections VF that are associated with the first surface F1 and branch off from the continuous surface region of the surface F1 in the first strip section. Other embodiments make provision of a two-part first surface, having a first part in the section LA and second parts (as connecting surface sections VF) in the section ZA, with the first part and the second part being connected by connecting elements, but collectively being associated with the same conductor track surface.

Connection surfaces P that are electrically isolated from the first surface (that is to say also from the connecting surface sections VF) (that is to say may assume different potentials) also extend in the intermediate section ZA. In FIG. 1, the connection surfaces P alternate with the connecting surface sections VF along the direction R1. The connecting surface sections VF extend starting from the first strip section LA to the second strip section HA and adjoin the second strip section HA. The connection surfaces P also extend in the intermediate section ZA from the first strip section LA to the second strip section HA (and are electrically isolated from the surface F2 in the intermediate section ZA in the conductor track surface). The extension of the connection surfaces P in the intermediate section ZA from the first strip section LA to the second strip section HA is perpendicular to the direction R1 (and along the carrier T).

The first surface F1 and the connection surfaces P are isolated from the second surface F2. There is a gap L between the intermediate section ZA and the second strip section HA. The gap electrically isolates the second surface (and thus the second strip section) from the first surface F or from its connecting surface sections VF and from the connection surfaces P. The gap L is illustrated in the form of a trench that runs along the direction R1. The thickness of the conductor track layer is completely cut through along the trench. The connection surfaces P are also isolated from the first surface F1 in that the conductor track layer has a gap running along a large part of the outer edge of the connection surfaces P. The connection surfaces are therefore isolated from the connecting surface sections VF and from the surface region of the first surface F1 that extends in the first strip section LA by a trench. The connection surfaces P (and also the first surface or its connecting surface sections VF) are separated from the second surface F2 by the illustrated gap L. This separation produces the electrical isolation of the second surface F2 from the first surface F1, as well as the electrical isolation of the second surface F2 from the connection surfaces P. For this purpose, the carrier T has an isolator layer on which the conductor track layer is formed.

The conductor track layer is therefore structured by the described trenches or gaps. The trenches or gaps define the layout of the conductor track layer. According to another view, the surfaces, or their outer edges, of the conductor track layer define the layout of the conductor track layer or the half-bridge module.

The connection surfaces P have a substantially rectangular cross section in schematic FIG. 1. This also applies to the connecting surface sections VF. However, this is one of many possibilities and is only intended to schematically illustrate that the connecting surface sections VF and the connection surfaces P together substantially fully fill the intermediate section ZA, that the connecting surface sections VF and the connection surfaces P extend substantially to the second surface F2 or to the second strip section HA, and that the connecting surface sections VF and the connection surfaces P are contacted from the second surface F2 with short connectors V′.

FIGS. 2a-2c schematically show some further embodiments of the geometric formation of the connection surfaces P or the connecting surface sections VF.

The embodiment of a half-bridge module M illustrated in FIG. 1 is a populated half-bridge module having first transistors LT and second transistors HT. The first transistors LT are provided on the first surface F1 in the first strip section LA. The first transistors are thus secured to a subregion of the first surface F1 that is continuous along the direction R1 (or located in the first strip section LA). The connecting surface sections VF extend from this continuous surface region of the first surface F1 to the second strip section HA.

The second transistors HT are provided on the second surface F2 and are thus situated in the second strip section HA. The second transistors HT are lined up together at regular intervals along the direction R1. The first transistors LT are also lined up together at regular intervals along the first direction R1 on the first surface F1 (in the first strip section LA). There are two rows of transistors located on opposite edge regions (that is to say in the separated first and second strip sections LA, HA) of the carrier T and the conductor track surface respectively. The connecting surface sections VF and the connection surfaces P extend between the first transistors on the one side and the second transistors on the other. In other words, the second strip section extends between the rows of transistors LT, HT, wherein the surfaces or surface sections provided there serve for connecting the transistors.

Within the conductor track layer, the connection surfaces P are electrically isolated from the first surface F1 (and also from the second surface F2). However, there are connectors V that connect the connection surfaces P to the transistors LT. A variant in which one connection surface is connected to multiple transistors (here: two) via multiple connectors V (two are illustrated) is illustrated. For this purpose, each transistor LT has a power path contact surface OK, from which the connector V extends to the connection surface P. The power path contact surfaces OK are metallization layers of the transistor LT and concern a power connection of the transistor (drain, source, emitter or collector). The connectors V may be wires, sheet metal pieces, conductive bridge elements, bonding tapes or bonding strips, for example made of an aluminum material or of a copper material or of another electrically conductive material. The illustration shows that the larger connection surfaces P (in FIG. 1, the three left connection surfaces P) are each connected to two transistors or to two contact surfaces OK. One connection surface P is smaller, namely the connection surface furthest to the right, and is connected to only one transistor LT. The connection surfaces P may thus be connected to different numbers of transistors at the same time, whereby the connection surfaces P may also be of different sizes.

The same applies to the connecting surface section VF that, as shown in FIG. 1, may have different widths (dimension in the direction of R1). The connecting surface section VF illustrated furthest on the left is less wide than the connecting surface sections VF following on the right. In this case, too, the connecting surface sections VF are connected to different numbers of transistors LT. The three larger connecting surface sections are connected to two transistors LT, while the narrower connecting surface section VF on the left is connected to only one transistor LT. Despite the different numbers or surface sizes or widths, however, there is no asymmetry from an electrical point of view. The second transistors HT also have respective power path contact surfaces OK′. These may be designed in the same way as the power surfaces power contact surfaces OK. The connecting surface sections VF are connected to corresponding contact surfaces OK′ of the transistors HT via respective connectors V′.

Each transistor LT is connected to one of the connection surfaces P illustrated. Each transistor LT is connected to one of the connecting surface sections VF illustrated. However, provision may be made of additional connecting surface sections or connection surfaces without a connection to a transistor, that is to say without a connection that leads via a connector V, V′.

FIG. 1 shows multiple groups of connection elements 1, 2, 3. The first group of connection elements 1 is located on the connecting surface sections VF. In general, the group of connection elements 1 is located on the first surface F1. Embodiments may therefore also be provided in which the first group of connection elements 1 are not provided as illustrated in the intermediate section ZA on the first surface F1, but are provided in the first strip section LA on the first surface F1. In other words, the connection elements may also be located on the surface region of the first surface F1 that is continuous in the direction R1, that is to say located in the first strip section LA. There are therefore two possibilities of placing the arrangement of the first group of connection elements 1. It is therefore a possibility to arrange a group of first connection elements 1 as illustrated on the connecting surface sections VF, or, as illustrated by the reference signs 1′, to place the first connection elements in a peripheral region of the first strip section LA facing away from the intermediate section ZA. A group of first connection elements 1′ arranged between the transistors LT of the first strip section LA are thus illustrated. The group of first connection elements 1 or else the first connection elements 1′ includes connection elements that are arranged in a manner distributed along the direction R1 (and spaced apart from one another). This enables the potential of the first surface to be connected at multiple points to a (first) connecting conductor that carries the potential of the first surface F1. This is a phase potential or a load potential and corresponds in electrical terms to the potential of the internal connection of the half-bridge.

A group of second connection elements 2 is also illustrated. Each illustrated connection surface P has (at least) one connection element 2. The connection elements 2 are provided to be connected to the same (second) connecting conductor, that is to say are connected to one another via same. The second connection elements are provided for carrying the same potential, such as a DC voltage supply potential (for example a negative supply potential). The group of second connection elements 2 is located on the connection surfaces P and thus in the intermediate section ZA.

In the embodiments illustrated, the group of first connection elements 1 and the group of second connection elements 2 are provided in two rows that extend along the direction R1 and are located in the intermediate section ZA. The use of connection elements arranged as illustrated by the reference sign 1 enables connecting paths to the different transistors LT, HT that are approximately of the same length. The connection elements illustrated by the reference sign 1′ enable a connection to the first surface F1 at points remote from the second strip section. In addition, these points are at least half the width of the first strip section away from the connection surfaces P or the connection elements 2.

A group of third connection elements 3 is provided in the second strip section HA, that is to say on the second surface F2. These connection elements are also arranged along a row that extends in the direction of R1. Generally, the different groups of connection elements 1, 1′, 2 and 3 are provided in each case in multiple rows that are offset to one another approximately perpendicular to the direction R1 (along the carrier T).

Connectors V that connect the contact surfaces OK of transistors LT to the connection surfaces P are illustrated. In the same way, connectors V′ that connect connecting surface sections VF to contact surfaces OK′ of transistors HT are illustrated. If the half-bridge module M is not populated with the transistors, then the layout alone enables the connectors V, V′ to be of appropriately short design and to be able to extend from the connecting surface sections VF or the connection surfaces P into the strip sections LA, HA. In an unpopulated embodiment, mounting surfaces for transistors or also connection elements for transistors, for example conductive connecting elements or the like, are located at the points where a transistor is denoted in FIG. 1.

FIG. 1 shows a populated half-bridge module M having transistors that in addition to the power contact surfaces OK, OK′ have signal contacts SK. Transistors having two signal contacts each are illustrated. These may be in the form of a gate connection or Kelvin connection (temperature signal connection) or sense connection (current measurement connection). Transistors having three signal contact surfaces SK, SK′ or having only one signal contact surface SK, SK′ may also be provided.

Since, in the layout of the conductor track layer illustrated in FIG. 1, both the connection surfaces P and the connecting surface sections VF extend between the two strip sections LA, HA, direct and short connection paths result both for transistors in the first strip section LA and for transistors in the second strip section HA so as to create a half-bridge. The LT transistors illustrated are connected in parallel with one another. This also applies to the transistors HT in the second strip section HA. The parallel connection results from the fact that the first transistors LT are mounted on the same first surface F1, and from the fact that the second transistors HT are all mounted on the second surface F2. Furthermore, the parallel connection of the first transistors LT results from the fact that a connection conductor (also referred to as connecting conductor), not illustrated, or a short-circuiting connection, not illustrated, contact-connects the connection surfaces P together, whereby these are short-circuited. Furthermore, the parallel connection of the second transistors HT results in that they are each connected (via connectors V′) to the first surface F1 or to connecting surface sections VF that converge in the first strip section, since the surface 1 is continuous there.

The connection elements 2 are connection elements of a negative potential, and the connection elements 3 are connections for a positive potential. These two potentials are potentials of a DC supply voltage. The connection elements 1 form connections for the potential of the connecting point or the internal connection between the two transistor elements of the half-bridge module illustrated, which connections result from the different transistor groups. The potential of the connection elements 1 may serve as a load connection or as a phase connection, for example for an electric machine. This is also true for the connection elements 1′. Provision may be made of a first connection conductor that is connected to the first connection elements 1. The first connection conductor may be a phase connection of the half-bridge module. Provision may be made of a second connection conductor that is connected to the second connection elements 2. The second connection conductor may be a negative supply potential conductor of the half-bridge module. Provision may be made of a third connection conductor that is connected to the third connection elements 3. The third connection conductor may be a positive supply potential conductor of the half-bridge module.

Provision may be made of filter circuits, such as snubbers, which may be arranged for example at the locations marked by a cross. These locations are in an edge region of the second surface adjacent to the intermediate section (or to the connection surfaces P). For example, the filter circuits may each be in the form of an SMD component mounted on the second surface F2. Furthermore, the filter circuits may also be connected to the connection surfaces by a bonding connection. If the filter circuit has a surface contact, the bonding connection may then extend from the connection surface P opposite the filter circuit to the surface contact. An SMD component of this kind furthermore has a further contact surface by way of which it is mounted on the second surface. The filter circuit may also be located on a connection surface P in an edge region of the connection surface P adjoining the second surface.

FIGS. 2a, b and c show further geometric embodiments for the illustration of the connection surfaces P and the connecting surface sections VF. The respective surfaces F1 of FIGS. 2a-2c correspond to the first surface F1 within the first strip section LA and within the surface region of the first surface F1 forming the connecting surface sections. A first subregion of the first surface F1 lies in the first strip section LA and is continuous in the direction R1. From the first subregion, the connecting surface sections VF pass to the second strip section HA or to the second surface F2. Connection surfaces P are provided in the intermediate section located between the first surface region of surface F1 and the second surface F2. It is schematically illustrated that the connecting surface sections VF and the connection surfaces P essentially fully cover the intermediate section (also with a part of the conductor track layer), wherein only gaps between the connecting surface sections VF and the connection surfaces P interrupt the otherwise continuous conductor track layer.

In FIG. 2a, the connection surface P has a, substantially rectangular, first region adjoining the continuous subregion of the first surface F1, whereupon a tapering section is connected in the direction of the second surface F2. A tapered portion in a trapezoidal shape is illustrated. It adjoins a further subregion, which is rectangular like the first subregion, but is narrower than this, in the direction of the second surface F2. The connecting surface section VF illustrated in FIG. 2 is designed to complement this. Starting from a subregion of the first surface F1, located in the first strip section, the illustrated connecting surface section VF extends in the direction of the second surface F2 substantially in accordance with a rectangle, to which a widening section is connected. In turn, a subregion that is also rectangular but is wider than the subregion mentioned first adjoins same in the direction of the second surface F2. FIG. 2a thus shows an isolated connection surface P in the form of a trapezoid, to which rectangles of different sizes are connected in a direction perpendicular to the parallel side pairs of the trapezoid.

FIG. 2b shows a further embodiment of an isolated connection surface P. This one has a first rectangular subregion to which a trapezoidal shape is connected in the direction of the second surface F2. As in FIG. 2a, in FIG. 2b, the relevant adjacent connecting surface section VF is formed in a complementary manner to the connection surface P. The subsequent trapezoidal shape, which tapers toward the second surface F2, adjoins the second surface F2.

FIG. 2c shows another embodiment having a trapezoidal connection surface P, whose wider side of the parallel side pair of the trapezoid adjoins the surface section of the first surface F1, located in the first strip section, while the shorter side of the parallel side pair of the trapezoid adjoins the second surface F2 (but does not make contact therewith). Here, too, it is seen that the connecting surface sections VF may generally be formed in a complementary manner to the connection surfaces P.

A trench between the connection surfaces P and the connecting surface sections VF runs around a large part of the connection surfaces P and has a substantially constant width along the profile. A trench is also provided between the second surface F2 on the one hand and the connecting surface sections VF and the connection surfaces P on the other.

This may also be provided with a constant width in the running direction. The two aforementioned trenches fully enclose the connection surfaces P such that the electrical insulation produced by the trenches within the conductor track layer leads to the connection surfaces P in the conductor track layer being electrical islands, that is to say are isolated within the structured conductor track layer (from surrounding regions). In addition to conductive surfaces, the conductor track layer also includes structures that ensure electrical interruption within the conductor track layer.

FIG. 3 shows an alternative embodiment of a filter circuit having a capacitor component C and a resistor component R. An intermediate island ZI, separated by a trench from both the second surface F2 and from the connection surfaces P and also from the first surface or from the connecting surface sections VF, is located between the second surface F2 and the connection surface P. The intermediate island ZI is a conductive surface isolated from the adjacent regions of the conductor track layer. The intermediate island ZI is located in an edge region of the second strip section HA facing the intermediate section ZA, in an edge region of the intermediate section ZA facing the second strip section HA, or in a region including the two edge regions.

Starting from the second surface F2, the resistor R bridges the trench between the second surface F2 and the intermediate island ZI. In other words, the resistor R connects the second surface F2 to the intermediate island. The intermediate island ZI is further connected via the capacitor C to the connection surface P, wherein the capacitor C bridges the trench between the intermediate island and the connection surface. The capacitor and the resistor may also be installed in reversed locations. The result is a series RC element, via which the second surface F2 is connected to the connection surface P. The RC element thus connects the two DC voltage supply potentials of the module as a high-pass filter.

The filter circuit illustrated in FIG. 3 may be arranged at or above the locations marked by a cross in FIG. 1. The intermediate island is formed as part of the conductor track layer. In the same way, the second surface, the first surface and the connection surface form parts of the conductor track layer, but they are separated from one another (within the conductor track layer).

The description of the invention is merely exemplary in nature and, thus, variations that do not depart from the gist of the invention are intended to be within the scope of the invention. Such variations are not to be regarded as a departure from the spirit and scope of the invention. This listing of claims will replace all prior versions, and listings, of claims in the application.

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. A half-bridge module comprising:
a carrier, further comprising:
a conductor track layer, further comprising:
a first transistor strip section;
a second transistor strip section; and
an intermediate section, each of the first transistor strip section, the second transistor strip section, and the intermediate section extending along a first direction such that the intermediate section is arranged between the first transistor strip section and the second transistor strip section;
a plurality of connecting surface sections being part of a first surface of the conductor track layer, the first surface also extends in the first transistor strip section;
wherein, in the intermediate section, the plurality of connecting surface sections of the first surface, and connection surfaces that are insulated therefrom, alternate in the first direction.

16. The half-bridge module of claim 15, wherein the plurality of connecting surface sections adjoin the second transistor strip section and are isolated therefrom and/or wherein the connection surfaces adjoin the first transistor strip section.

17. The half-bridge module of claim 15, wherein the plurality of connecting surface sections get wider toward the second transistor strip section and/or wherein the connection surfaces taper toward the second transistor strip section.

18. The half-bridge module of claim 15, wherein a portion of the first surface in the first transistor strip section extends as a strip that is continuous in the first direction, and the plurality of connecting surface sections extend from the strip toward the second transistor strip section.

19. The half-bridge module of claim 15, the conductor track layer further comprising:
a second surface that is isolated from the first surface and from the connection surfaces, the second surface further comprising:
a plurality of mounting surfaces for transistors that extend in one or more rows along the first direction extends in the second transistor strip section.

20. The half-bridge module of claim 15, the first surface in the first transistor strip section further comprising mounting surfaces for transistors that extend in one or more rows along the first direction.

21. The half-bridge module of claim 15, further comprising a plurality of connection elements, a first portion of the plurality of connection elements provided on the first surface, a second portion of the plurality of connection elements provided on the connection surfaces, and third portion of the plurality of connection elements provided in the second transistor strip section.

22. The half-bridge module of claim 21, wherein each of the plurality of connection elements is a sintering pad, soldering pad, welding surface, connection pin, connection plate piece, or a mounting hole.

23. The half-bridge module of claim 21, wherein the first portion of connection elements located on the first surface is provided in the intermediate section or located with a deviation in the center between a row of transistor mounting surfaces in the first transistor strip section and a row of transistor mounting surfaces in the second transistor strip section.

24. The half-bridge module of claim 15, further comprising a plurality of first connectors, each of which is connected to a corresponding one of the connection surfaces and extends over the carrier into the first transistor strip section,

25. The half-bridge module of claim 24, further comprising a plurality of second connectors, each of which is connected to a corresponding one of the connecting surface sections and extends over the carrier into the second transistor strip section.

26. The half-bridge module of claims 15, further comprising:
a plurality of first transistors; and
a plurality of second transistors;
wherein the first surface of the conductor track layer in the first transistor strip section is populated with the plurality of first transistors and a second surface that extends in the second transistor strip section is populated with the plurality of second transistors.

27. The half-bridge module of claim 26, further comprising:
a plurality of first power path contact surfaces of the plurality of first transistors which are connected to the first surface;
a plurality of second power path contact surfaces of the plurality of first transistors which are connected to the connection surfaces by a corresponding one of a plurality of first connectors extending over the carrier;
a plurality of first power path contact surfaces of the plurality of second transistors which are connected to the second surface; and
a plurality of second power path contact surfaces of the plurality of second transistors which are connected to the connecting surface sections by a corresponding one of a plurality of second connectors extending over the carrier.

28. The half-bridge module of claim 26, further comprising:
a low-side transistor element;
a high-side transistor element; and
an internal connection between the low-side transistor element and the high-side transistor element;
wherein the low-side transistor element is formed by the plurality of first transistors, the high-side transistor element is formed by the plurality of second transistors, and the internal connection comprises the first surface.

29. The half-bridge module of claim 26, further comprising:
a first plurality of signal contact surfaces, each of the plurality of first transistors having one or more of the first plurality of signal contact surfaces;
a second plurality of signal contact surfaces, each of the plurality of second transistors having one or more of the second plurality of signal contact surfaces;
wherein each of the first plurality of signal contact surfaces are provided on one side of the plurality of first transistors facing away from the intermediate section, and each of the second plurality of signal contact surfaces are provided on one side of the plurality of second transistors facing away from the intermediate section.

30. The half-bridge module of claim 15, further comprising at least one filter circuit, wherein the at least one filter circuit is arranged in the second transistor strip section and/or on the connection surfaces.
